(19) United States
(12) Patent Application Publication
(10) Pub. No.: US 2021/0141011 A1
(43) Pub. Date: May 13, 2021

(54) METHOD AND SYSTEM FOR CHARACTERISING A FAULT IN A NETWORK OF TRANSMISSION LINES, BY TIME REVERSAL

(71) Applicant: COMMISSARIAT A L'ENERGIE ATOMIQUE ET AUX ENERGIES ALTERNATIVES, PARIS (FR)

(72) Inventors: Wafa BEN HASSEN, PARIS (FR); Esteban CABANILLAS, ORSAY (FR); Moussa KAFAL, LES ULIS (FR)

(21) Appl. No.: 17/253,542

(22) PCT Filed: Jun. 13, 2019
(86) PCT No.: PCT/EP2019/065464

§ 371 Date: Dec. 17, 2020

(30) Foreign Application Priority Data
Jun. 29, 2018 (FR) 1855942

(51) Int. Cl. G01R 31/11; G01R 31/08; G01R 27/06

(52) U.S. Cl. CPC G01R 31/11; G01R 27/06; G01R 31/083; G01R 31/088

(57) ABSTRACT

A method for characterizing a fault in a network of at least one transmission line, the method includes the steps of: injecting a first reference signal into the network, acquiring a first measurement of the first reference signal after its propagation in the network, temporally reversing the measurement to generate a second reference signal, injecting the second reference signal into the network, acquiring a second measurement of the second reference signal after its propagation in the network, calculating the intercorrelation between the second measurement and the second reference signal.

The invention relates to the field of wire diagnostic systems based on the principle of reflectometry. Its subject is a method for characterizing a fault in a transmission line network, based on the principle of time reversal.

Cables are omnipresent in all electrical systems, for power supply or information transmission. These cables are subjected to the same stresses as the systems that they link and can be subject to failures. It is therefore necessary to be able to analyze their state and provide information on the detection of faults, but also the location and the type thereof, in order to assist in maintenance. The normal reflectometry methods allow this type of testing.

Reflectometry methods use a principle similar to that of radar: an electrical signal, the probe signal or reference signal, which is more often than not of high frequency or wide band, is injected at one or more points of the cable to be tested. The signal is propagated in the cable or the network and returns a portion of its energy when it encounters an electrical discontinuity. An electrical discontinuity can result, for example, from a connection, the end of the cable or a fault or, more generally, a break in the conditions of propagation of the signal in the cable. Most often, it results from a fault which locally modifies the characteristic impedance of the cable by provoking a discontinuity in its line parameters.

The analysis of the signals returned to the point of injection allows information to be deduced concerning the presence and the location of these discontinuities, therefore of any faults. An analysis in the time or frequency domain is usually performed. These methods are referred to by the acronyms TDR, from the expression “Time Domain Reflectometry”, and FDR, from the expression “Frequency Domain Reflectometry”.

The invention lies within the scope of the reflectometry methods for wire diagnostic purposes and applies to any type of electrical cable, in particular power transmission cables or communication cables, in fixed or mobile installations. The cables concerned can be coaxial, twin-wired, in parallel lines, in twisted pairs or other types, provided that it is possible to inject into them a reflectometry signal at a point of the cable and to measure its reflection at the same point or at another point.

The known time reflectometry methods are particularly suited to the detection of hard faults in a cable, such as a short circuit or an open circuit or, more generally, a significant local modification of the impedance of the cable. The detection of the fault is done by measuring the amplitude of the signal reflected on this fault which is all the greater and therefore detectable when the fault is significant.

Conversely, a soft fault, for example resulting from a superficial degradation of the sheath of the cable, of the insulation or of the conductor, generates a low amplitude peak on the reflectometry signal reflected and is consequently more difficult to detect by conventional temporal methods. More generally, a soft fault can be provoked by friction, pinching or even a phenomenon of corrosion which affects the sheath of the cable, the insulation or the conductor.

The detection and the locating of a soft fault on a cable is a significant problem for the industrial world because a fault generally appears first of all as a superficial fault but can, over time, evolve to a more impactful fault. For that reason in particular, it is useful to be able to detect the occurrence of a fault as soon as it appears and at a stage where its impact is superficial in order to anticipate its evolution to a more significant fault.

The low amplitude of the reflections associated with the passage of the signal through a soft fault also leads to a potential problem of false detections. Indeed, it can be difficult to discriminate a low amplitude peak in a reflectogram which can result either from a fault on the cable or from a measurement noise. Thus, false positives can appear which correspond not to faults but which result from the measurement noise or the nonuniformities of the cable.

The American patent U.S. Pat. No. 9,465,067 describes a method for locating faults in a power cable network, based on the principle of time reversal.

This method consists in recording a signal generated by an intermittent fault which is propagated to a measurement point then in temporally reversing the measurement to inject it into the network and finally in measuring the reflected signal.

The proposed method is suited to the intermittent faults which spontaneously generate a shock wave but not to the passive permanent faults, in particular the soft faults.

Moreover, this method cannot be used on a cable network in operation, that is to say in which useful signals are also being transmitted.

The scientific publication “Time Reversal for soft faults diagnosis in wire networks”, by Lola El Sahmarany et al., Progress in Electromagnetics Research M, vol 31, 2013, describes another method for characterizing soft faults based on the principle of time reversal. It consists this time in injecting a reference signal into a cable, in measuring its echo, then in temporally reversing this echo to reinject it once again into the cable.

This method primarily includes the following three steps. First of all, a probe signal vᵢₙ is injected into the healthy transmission line on the one hand and into the transmission line with a fault on the other hand. The reflected signals measured on the line with a fault, denoted v_{rF}, and on the line without a fault, denoted v_{rS}, are recorded.

Next, the reflected signals for the healthy line and the line with a fault are temporally reversed and reinjected into the healthy transmission line to obtain, respectively, the reflected signals v_{rFbis} and. v_{rSbis}. A correlation is then determined between the reflected signal v_{rFbis} and the probe signal vᵢₙ, then a correlation is determined between the reflected signal v_{rbis} and the probe signal vᵢₙ. The difference between the two correlation results allows the fault to be detected and located.

This method presents the drawback of requiring a measurement to be performed both on a healthy cable (without fault) and on the same cable with fault. It also does not allow a diagnosis to be made on a cable in operation. Indeed, the signals injected into the cable via this method can disrupt the nominal operation of the cable by generating interferences.

Also known are multicarrier reflectometry methods as described notably in the international patent application from the Applicant published under the number WO2015062885.

Such methods are based on the use of a multicarrier signal of OFDM (Orthogonal Frequency Division Multiplexing) type. The principle is to divide the available frequency band into orthogonal sub-bands so as to maximize the spectral efficiency while controlling the spectrum of the signal. By applying this principle, some frequency bands reserved for the nominal use of the cable are avoided by eliminating the corresponding subcarriers from the signal. That way, it is possible to generate a signal that has a spectral occupancy only on frequency sub-bands authorized for fault diagnosis.

Thus, the use of reflectometry methods based on a multicarrier signal allows an inline diagnosis to be performed on a cable network without interfering with the nominal operation of the network and without requiring the service provided by the network to be interrupted.

However, such methods present the drawback of suffering from an attenuation of the signal that is significant, which reduces the reliability of detection of the faults by analysis of the reflectogram.

The invention aims to propose a method, based on the principle of time reversal, of detecting and locating faults which allows the detection gain and the location accuracy to be improved and which can be implemented without disturbing the nominal operation of the cable network.

The subject of the invention is a method for characterizing a fault in a network of at least one transmission line, said method comprising the steps of:
injecting a first reference signal into the network,
acquiring a first measurement of the first reference signal after its propagation in the network,
temporally reversing the measurement to generate a second reference signal,
injecting the second reference signal into the network,
acquiring a second measurement of the second reference signal after its propagation in the network,
calculating the intercorrelation between the second measurement and the second reference signal.

According to a particular aspect of the invention, the first reference signal is a signal comprising a plurality of frequency carriers.

According to a particular variant, the method according to the invention further comprises the search, in the intercorrelation, for at least one extremum indicating the presence of a fault.

Another subject of the invention is a system for characterizing a fault in a network of at least one transmission line, the system comprising means configured to implement the steps of the method for characterizing a fault according to the invention.

According to a particular variant, the system according to the invention comprises:
a generator of a reference signal,
an injection device for injecting the reference signal into the network,
a measurement device for measuring the reference signal after its propagation in the network,
a logic unit configured to save a time measurement acquired by the measurement device and to deliver, to the injection device, a temporally reversed version of said measurement,
a correlator,
a first connector configured to connect, in a first phase, the reference signal generator to the injection device and, in a second phase, the logic unit to the injection device,
a second connector configured to connect, in the first phase, the measurement device to the logic unit and, in a second phase, the measurement device to the correlator,
the correlator being connected on one side to the logic unit and on the other side to the second connector and being configured to determine the intercorrelation between the signal measured by the measurement device during the second phase and the temporally reversed measurement delivered by the logic unit.

According to a particular aspect of the invention, the logic unit is a memory capable of saving a time measurement of a signal and of supplying the samples of the saved measurement in a reverse order to that in which they were saved.

According to a particular aspect of the invention, the generator of a reference signal comprises a generator of frequency subcarriers and an inverse Fourier transform module.

According to a particular aspect of the invention, the first connector and/or the second connector are switches.

According to a particular aspect of the invention, the correlator comprises at least one direct Fourier transform module, a multiplier and an inverse Fourier transform module.

Other features and advantages of the present invention will become more apparent on reading the following description in relation to the attached drawings which represent:

FIG. 1, a diagram of a reflectometry system according to the prior art,

FIG. 1bis, an example of reflectogram obtained with the reflectometry system of FIG. 1 for a simple cable,

FIG. 2, a diagram of a reflectometry system according to an embodiment of the invention,

FIG. 3, a flow diagram describing the steps of implementation of the method according to the invention,

FIGS. 4a, 4b, 4c, three time diagrams representing comparative examples of reflectograms obtained with and without the invention.

FIG. 1 represents a diagram of a system 100 for analyzing faults in a transmission line L, such as a cable, according to a standard time reflectometry method of the prior art. Such a system primarily comprises a generator GEN of a reference signal. The digital reference signal generated is converted to analog via a digital-analog converter DAC then is injected at a point of the transmission line L by means of a directional coupler CPL or any other device allowing a signal to be injected into a line. The signal is propagated along the line and is reflected on the singularities that it includes. In the absence of a fault on the line, the signal is reflected on the end of the line if the termination of the line is not matched. In the presence of a fault on the line, the signal is reflected partially on the impedance discontinuity provoked by the fault. The reflected signal is back-propagated to a measurement point, which can be the same as the injection point or different. The back-propagated signal is measured via the directional coupler CPL then converted to digital by an analog-digital converter ADC. A correlation COR is then performed between the measured digital signal and a copy of the digital signal generated before injection in order to produce a time reflectogram R(t) corresponding to the intercorrelation between the two signals.

As is known in the field of time reflectometry diagnostic methods, the position d_{DF} of a fault on the cable L, in other words its distance to the point of injection of the signal, can be directly obtained from the measurement, on the calculated time reflectogram R(t), of the time t_{DF} between the first amplitude peak recorded on the reflectogram and the amplitude peak corresponding to the signature of the fault.

FIG. 1bis represents an example of reflectogram R(n) obtained using the system of FIG. 1, on which a first amplitude peak is observed at an abscissa N and a second amplitude peak is observed at an abscissa N+M. The first amplitude peak corresponds to the reflection of the signal at the point of injection into the cable, while the second peak corresponds to the reflection of the signal on the impedance discontinuity provoked by a fault.

Various known methods can be envisaged for determining the position d_{DF}. A first method consists in applying the relationship linking distance and time: d_{DF}=V_{g}·t_{DF}/2 in which V_{g} is the speed of propagation of the signal in the cable. Another possible method consists in applying a proportionality relationship of the type d_{DF}/t_{DF}=L_{c}/t₀ in which L_{c} is the length of the cable and t₀ is the time, measured on the reflectogram, between the amplitude peak corresponding to the impedance discontinuity at the point of injection and the amplitude peak corresponding to the reflection of the signal on the end of the cable.

An analysis device (not represented in FIG. 1) is responsible for analyzing the reflectogram R(t) to deduce therefrom information on the presence and/or location of faults and the possible electrical characteristics of the faults. In particular, the amplitude of a peak in the reflectogram is directly linked to the coefficient of reflection of the signal on the impedance discontinuity provoked by the fault.

The device of FIG. 1 can be applied to the case of a multicarrier signal by replacing the reference signal generator with a generator of subcarriers, possibly modulated, coupled to an inverse Fourier transform module.

FIG. 2 describes a reflectometry system 200 according to an embodiment of the invention.

It comprises a generator GEN of subcarriers and a first inverse Fourier transform module IFFT₁ for generating a multicarrier reference signal. Without departing from the scope of the invention, the multicarrier signal can be replaced by any other controlled signal, in particular any signal representing good self-correlation properties. If the signal used is a time-domain signal and no longer a frequency domain signal, the module IFFT₁ is eliminated from the system.

If the signal generated by the generator GEN is a digital signal, the system 200 includes a digital-analog converter DAC.

The system 200 also comprises a coupler CPL, or any other equivalent device, for injecting the reference signal into a cable L. The system 200 also comprises a device for measuring the signal reflected in the cable L which can be performed by the same coupler CPL or another coupler.

The system 200 also comprises an analog-digital converter ADC for digitizing the measured signal, at least a first memory MEM₁ for saving the digitized signal and a second memory MEM₂ for saving a copy of the temporally reversed memorized signal. The two memories MEM₁, MEM₂ can be merged into a single memory associated with a read index capable of reading the signal samples memorized in the reverse order of which they were recorded.

Moreover, the system 200 comprises a first switch INT₁ for alternately connecting the input of the digital-analog converter DAC to the output of the signal generator or to the output of the memory MEM₂, a second switch INT₂ for alternately connecting the input of the analog-digital converter ADC to the input of the memory MEM₁ or to a first input of a correlator COR whose second input is linked to the output of the memory MEM₂.

In a first phase of operation of the system 200, the first switch INT₁ is set so as to link the signal generator GEN to the digital-analog converter DAC (position A in FIG. 2). The reference signal is then injected into the cable L. In this first phase of operation, the second switch INT₂ is set so as to link the output of the analog-digital converter ADC to the memory MEM₁ (position A in FIG. 2). The reflected signal is sampled by the coupler CPL, digitized then saved in the memory MEM₁. A temporally reversed copy of the measurement is saved in the memory MEM₂.

In a second phase of operation of the system 200, the first switch INT₁ is set so as to link the memory MEM₂ to the digital-analog converter DAC (position B in FIG. 2) to inject into the cable L, the time-reversed signal memorized in the memory MEM₂. In a particular variant of the invention, a single memory is available and the time-reversed signal is directly read in the memory in a reverse order of the order of recording of the signal during the first phase.

The second switch INT₂ is set so as to link the output of the analog-digital converter ADC to an input of the correlator COR (position B in FIG. 2). The signal injected into the cable in the second phase of operation is back-propagated to the coupler CPL, which takes a measurement of this signal which is then digitized and supplied to an input of the correlator COR. The correlator COR calculates the intercorrelation between this signal and the time-reversed signal saved in the memory MEM₂.

According to one embodiment of the invention, the injection of the signal and the measurement of the back-propagated signal are performed at the same point of the cable, for example at an end of the cable.

An exemplary embodiment of the correlator COR is given in FIG. 2. It comprises a direct Fourier transform module FFT₁ linked to the first input of the correlator, the second direct Fourier transform module FFT₂ linked to the second input of the correlator, a multiplier MUL for multiplying the outputs of the two direct Fourier transform modules and an inverse Fourier transform module IFFT₂ linked to the output of the multiplier. According to a variant, the first direct Fourier transform module FFT₁ and the second direct Fourier transform module FFT₂ are replaced by a single direct Fourier transform module.

The system 200 according to any of the variant embodiments of the invention can be implemented by an electronic circuit board on which the various components are arranged. The board can be connected to the cable to be analyzed by a coupling means CPL which can be a directional coupler with capacitive or inductive effect or even an ohmic connection. The coupling device can be produced by physical connectors which link the signal generator to the cable or by contactless means, for example by using a metal cylinder whose internal diameter is substantially equal to the outer diameter of the cable and which produces a capacitive coupling effect with the cable.

Furthermore, a processing unit, of computer, personal digital assistant or other equivalent electronic or computing device type can be used to drive the system according to the invention and display the results of the calculations performed by the correlator COR on a human-machine interface, in particular the information on detection and location of faults on the cable.

The different components of the system 200 according to the invention can be implemented by means of software and/or hardware technology. In particular, the invention can be implemented totally or partially by means of an embedded processor or a specific device. The processor can be a generic processor, a specific processor, an application-specific integrated circuit (also known by the acronym ASIC) or field-programmable gate array (also known by the acronym FPGA). The system according to the invention can use one or more dedicated electronic circuits or a general-purpose circuit. The technique of the invention can be implemented on a reprogrammable computation machine (a processor or a microcontroller for example) running a program comprising a sequence of instructions, or on a dedicated computation machine (for example a set of logic gates such as an FPGA or an ASIC, or any other hardware module).

FIG. 3 describes the steps of implementation of the method for characterizing a fault according to the invention. The method is implemented by means of a system 200 of the type of that described in FIG. 2.

In a first step 301, a first reference signal is injected into the transmission line network L that is to be diagnosed.

In a second step 302, the signal back-propagated after its propagation in the network is measured, as are any reflections thereof on the impedance discontinuities provoked by the presence of a fault but also by joins or terminations of the network.

In a third step 303, a time reversal is applied to the measured signal to reverse the order of the samples of the signal.

In a fourth step 304, the signal obtained in the step 303 is injected into the network.

In a fifth step 305, the back-propagated signal is measured again, then, in a sixth step 306, the intercorrelation between the signal measured in the step 305 and the signal obtained after the time-reversal step 303 is calculated.

The result of the intercorrelation calculation is a time reflectogram, the analysis of which makes it possible to detect and locate a fault in the network of lines.

The invention thus allows the signature of a fault to be amplified in the reflectogram obtained, by comparison to the methods of the prior art, because the use of time reversal makes it possible to generate, in the step 303, a signal matched to the cable faults. Indeed, the signal measured in the step 302 comprises reflection echoes of the initial signal injected in the step 301 on the cable faults. By temporally reversing this signal and by injecting it into the cable, a superimposition of the reflections obtained via the first injection 301 and of the reflections obtained via the second injection 304 is induced.

The signal obtained in step 305 then comprises an aggregation of the echoes of the signal constructed in the step 303 and of the echoes linked to the reflection of this signal injected in the step 304 then measured in the step 305.

Ultimately, the intercorrelation between the signal measured in the step 305 and the signal generated in the step 303 presents a significant gain compared to a reference signal which would not be matched to the cable faults.

FIGS. 4a, 4b and 4c represent the time reflectograms obtained respectively with the invention and with a method of the prior art.

The method of the prior art is based on the principle described in the publication “Time Reversal for soft faults diagnosis in wire networks”, by Lola El Sahmarany et al., Progress in Electromagnetics Research M, vol 31, 2013.

FIG. 4a represents a reflectogram 400 obtained with the invention and a reflectogram 401 obtained with a method of the prior art based on time reversal, for a cable 10 meters long without faults. The amplitude peak P₀, P₁ measured on the two reflectograms corresponds to the termination of the cable in open circuit mode. Note that the peak P₀ of the reflectogram 400 obtained with the present invention has a higher amplitude than the peak P₁ of the reflectogram 401 obtained with the method of the prior art.

FIG. 4b represents a reflectogram 500 obtained with the invention and a reflectogram 501 obtained with the method of the prior art based on time reversal, for a cable having a capacitive fault 2 cm long at 10 m from the point of injection of the signal.

It can be seen that the signature of the capacitive fault P₂ has a higher amplitude on the reflectogram 500 obtained with the invention than that P₃ measured on the reflectogram 501 obtained with the method of the prior art.

FIG. 4c represents a reflectogram 600 obtained with the invention and a reflectogram 601 obtained with the method of the prior art based on time reversal, for a cable having a resistive fault 2 cm long at 20 m from the point of injection of the signal.

Here again, it can be seen that the signature of the capacitive fault P₄ has a higher amplitude on the reflectogram 600 obtained with the invention than that P₅ measured on the reflectogram 601 obtained with the method of the prior art.

The invention notably has the following differences with respect to the abovementioned method of the prior art.

The invention does not require the use of a healthy cable unlike the method of the prior art. Nor does it require two correlations to be calculated, but only one. Moreover, the invention involves a calculation of correlation between the signal time-reversed then injected into the cable and the measurement of this same signal after reflection. On the contrary, in the method of the prior art, the correlation is applied between the first reference signal injected in the step 301 and the final signal measured after reflection obtained in the step 305. Finally, the invention allows the complexity of implementation of the method to be reduced, in other words the number of calculations or operations necessary to its execution.

Moreover, by using a multicarrier reference signal of OFDM type, the invention allows a diagnosis of the state of health of a transmission line network to be established without requiring the service supplied by the network to be interrupted or generating interferences for this service.

1. A method for characterizing a fault in a network of at least one transmission line, said method comprising the steps of:
injecting a first reference signal into the network,
acquiring a first measurement of the first reference signal after its propagation in the network,
temporally reversing the measurement to generate a second reference signal,
injecting the second reference signal into the network,
acquiring a second measurement of the second reference signal after its propagation in the network,
calculating the intercorrelation between the second measurement and the second reference signal.

2. The method for characterizing a fault as claimed in claim 1, wherein the first reference signal is a signal comprising a plurality of frequency-domain carriers.

3. The method for characterizing a fault as claimed in claim 1, further comprising the search, in the intercorrelation, for at least one extremum indicating the presence of a fault.

4. A system for characterizing a fault in a network of at least one transmission line, the system comprising means configured to implement the steps of the method for characterizing a fault as claimed in claim 1.

5. The system for characterizing a fault as claimed in claim 4, the system comprising:
a generator (GEN) of a reference signal,
an injection device (DAC,CPL) for injecting the reference signal into the network,
a measurement device (CPL,ADC) for measuring the reference signal after its propagation in the network,
a logic unit (MEM₁,MEM₂) configured to save a time measurement acquired by the measurement device (CPL,ADC) and to deliver, to the injection device (DAC,CPL), a temporally reversed version of said measurement,
a correlator (COR),
a first connector (INT₁) configured to connect, in a first phase, the reference signal generator (GEN) to the injection device (DAC,CPL) and, in a second phase, the logic unit (MEM₂) to the injection device (DAC,CPL),
a second connector (INT₂) configured to connect, in the first phase, the measurement device (CPL,ADC) to the logic unit (MEM₁) and, in a second phase, the measurement device (CPL,ADC) to the correlator (COR),
the correlator (COR) being connected on one side to the logic unit (MEM₂) and on the other side to the second connector (INT₂) and being configured to determine the intercorrelation between the signal measured by the measurement device (CPL,ADC) during the second phase and the temporally reversed measurement delivered by the logic unit (MEM₂).

6. The system for characterizing a fault as claimed in claim 5, wherein the logic unit (MEM₁,MEM₂) is a memory capable of saving a time measurement of a signal and of supplying the samples of the saved measurement in a reverse order to that wherein they were saved.

7. The system for characterizing a fault as claimed in claim 5, wherein the generator (GEN) of a reference signal comprises a frequency subcarrier generator and an inverse Fourier transform module (IFFT₁).

8. The system for characterizing a fault as claimed in claim 5, wherein the first connector (INT₁) and/or the second connector (INT₂) are switches.

9. The system for characterizing a fault as claimed in claim 5, wherein the correlator (COR) comprises at least one direct Fourier transform module (FFT₁,FFT₂), a multiplier (MUL) and an inverse Fourier transform module (IFFT₂).
